(19) United States
(12) Patent Application Publication
(10) Pub. No.: US 2025/0253643 A1
(43) Pub. Date: Aug. 7, 2025

(54) TEMPERATURE COMPENSATION CIRCUIT, SEMICONDUCTOR INTEGRATED CIRCUIT, SEMICONDUCTOR DEVICE, AND TEMPERATURE COMPENSATION METHOD

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Reiji TAGOMORI, Yokohama (JP); Yoshiharu NITO, Yokohama (JP); Shoji OOTAKA, Yokohama (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/190,895

(22) Filed: Apr. 28, 2025

Related U.S. Application Data
(63) Continuation of application No. PCT/JP2024/007625, filed on Feb. 29, 2024.

(30) Foreign Application Priority Data
Jul. 13, 2023 (JP) 2023-115515

(51) Int. Cl. H02H 7/125

(52) U.S. Cl. CPC H02H 7/125

(57) ABSTRACT

According to one embodiment, a temperature compensation circuit that includes a correction circuit and a voltage supply circuit is provided. The correction circuit includes a first input node, a second input node, and an output node. The first input node is connected to a temperature sensor near a power device. The second input node is connected to a control terminal of the power device. The voltage supply circuit includes an input node and an output node. The input node is connected to the output node of the correction circuit. The output node is connected to a second input node of a comparator circuit. The comparator circuit includes a first input node and the second input node. The first input node is connected to one end of the power device.

### CROSS-REFERENCE TO RELATED APPLICATIONS

This application is based upon and claims the benefit of priority from Japanese Patent Application No. 2023-115515, filed on Jul. 13, 2023; the entire contents of which are incorporated herein by reference.

### FIELD

Embodiments described herein relate generally to a temperature compensation circuit, a semiconductor integrated circuit, a semiconductor device, and a temperature compensation method.

### BACKGROUND

A semiconductor device that is connected to a control terminal of a power device drives the power device. The power device is connected to a load that operates at a relatively large current, and is used to switch the load. It is desired that the semiconductor device appropriately protect the power device against overcurrent.

### BRIEF DESCRIPTION OF THE DRAWINGS

FIG. 1 is a circuit diagram illustrating a configuration of a semiconductor device according to an embodiment;

FIGS. 2A to 2D are diagrams for explaining DESAT according to the embodiment;

FIG. 3 is a circuit diagram illustrating a configuration of a temperature sensor according to the embodiment;

FIG. 4 is a circuit diagram illustrating a configuration of a temperature compensation circuit according to the embodiment;

FIG. 5 is a sequence diagram illustrating an operation of the temperature compensation circuit according to the embodiment;

FIG. 6 is a waveform diagram illustrating an operation of the semiconductor device according to the embodiment;

FIGS. 7A and 7B are diagrams illustrating an operation of the temperature compensation circuit according to the embodiment;

FIG. 8 is a diagram illustrating a configuration of a temperature sensor according to a first variation of the embodiment;

FIG. 9 is a circuit diagram illustrating a configuration of a temperature compensation circuit according to a second variation of the embodiment;

FIG. 10 is a sequence diagram illustrating an operation of the temperature compensation circuit according to the second variation of the embodiment;

FIG. 11 is a diagram illustrating a data structure of correction information according to the second variation of the embodiment;

FIGS. 12A and 12B are diagrams illustrating an operation of a correction circuit according to a third variation of the embodiment; and

FIGS. 13A and 13B are diagrams illustrating an operation of a correction circuit according to a fourth variation of the embodiment.

### DETAILED DESCRIPTION

In general, according to one embodiment, there is provided a temperature compensation circuit including a correction circuit and a voltage supply circuit. The correction circuit includes a first input node, a second input node, and an output node, the first input node being connected to a temperature sensor near a power device, the second input node being connected to a control terminal of the power device. The voltage supply circuit includes an input node and an output node, the input node being connected to the output node of the correction circuit, the output node being connected to a second input node of a comparator circuit that includes the first input node and the second input node, the first input node being connected to one end of the power device.

Exemplary embodiments of a semiconductor device will be explained below in detail with reference to the accompanying drawings. The present invention is not limited to the following embodiments.

### Embodiment

The semiconductor device according to the embodiment is connected to a control terminal of a power device, and drives the power device. The semiconductor device is designed to appropriately protect the power device against overcurrent.

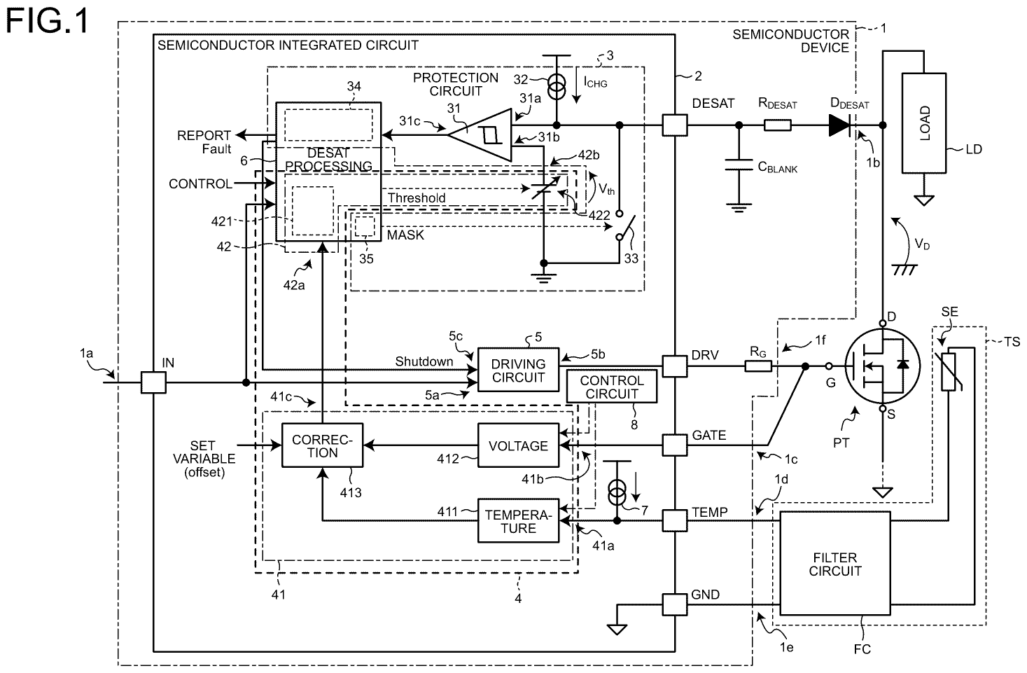

A semiconductor device 1 may be connected to a control terminal G of a power device PT, as illustrated in FIG. 1, and may drive the power device PT. FIG. 1 is a circuit diagram illustrating a configuration of the semiconductor device 1.

The power device PT is connected to a load LD that operates at a relatively large current, and is used to switch the load LD. The load LD may be a portion of a direct current motor and its driving circuit (for example, an H-bridge circuit), and the power device PT may be another portion of the driving circuit. Alternatively, the load LD may be a portion of an alternating current motor and its driving circuit (for example, an inverter circuit), and the power device PT may be another portion of the driving circuit.

As the power device PT, an arbitrary device that can handle a relatively large current can be employed. The power device PT may be an insulated gate bipolar transistor (IGBT), may be a power metal-oxide-semiconductor field-effect transistor (MOSFET), or may be a bipolar transistor. A substrate to be used for a device structure of the power device PT may be a SiC substrate or may be a Si substrate.

If malfunction such as a short circuit has occurred in the load LD, there is a possibility that overcurrent will flow through the power device PT. In order to protect the power device PT against overcurrent, it is effective to detect that overcurrent has started to flow through the power device PT, and perform a protection operation to turn off the power device PT in response to detection. It can be detected that overcurrent has started to flow through the power device PT, by detecting DESAT (hereinafter referred to as DESAT detection).

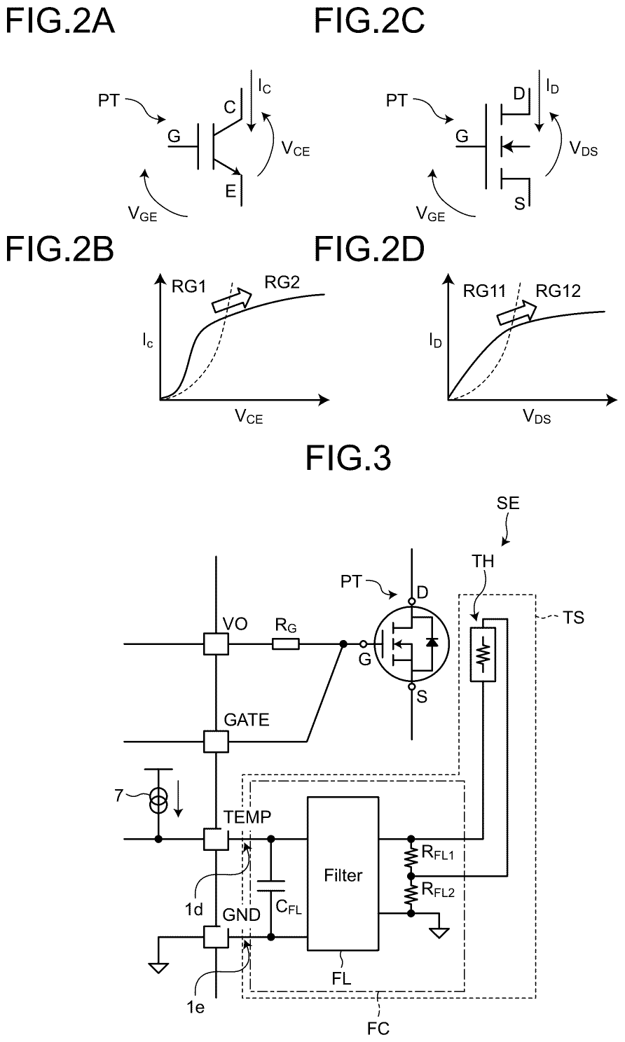

DESAT can be defined as illustrated in FIGS. 2A to 2D. FIGS. 2A to 2D are diagrams for explaining DESAT.

For example, in a case where the power device PT is an N-type IGBT, one end of the power device PT is a collector C, another end is an emitter E, and a control terminal is a gate G, as illustrated in FIG. 2A.

When a voltage V_{GE} between the gate G and the emitter E has exceeded a predetermined value, and the power device PT has been turned on, in a region RG1, a current I_{C} that flows from the collector C to the emitter E steeply increases in accordance with an increase in a voltage V_{CE} between the collector C and the emitter E, as illustrated in FIG. 2B. In a region RG2 on a higher-voltage side, the current I_{C} gently increases in accordance with an increase in the voltage V_{CE}.

A transition from the region RG1 of a steep current I_{C} to the region RG2 of a gentle current I_{C}, as illustrated as a void arrow in FIG. 2B, is referred to as DESAT (desaturation). The region RG1 is called a saturated region. The region RG2 is called an active region.

Note that a case where the power device PT is a P-type IGBT is similar to a case where the power device PT is the N-type IGBT, excluding that a voltage between the gate G and the emitter E that causes an ON state has a reverse polarity, and a collector current flows in a direction from the emitter E to the collector C.

As another example, in a case where the power device PT is an N-type power MOSFET, one end of the power device PT is a drain D, another end is a source S, and a control terminal is a gate G, as illustrated in FIG. 2C.

When a voltage V_{G}S between the gate G and the source S has exceeded a predetermined value, and the power device PT has been turned on, in a region RG11, a current I_{D} of the drain D steeply increases in accordance with an increase in a voltage V_{D}s between the drain D and the source S, as illustrated in FIG. 2D. In a region RG12 on a higher-voltage side, the current I_{D} gently increases in accordance with an increase in the voltage VD.

A transition from the region RG11 of a steep current I_{D} to the region RG12 of a gentle current I_{D}, as illustrated as a void arrow in FIG. 2D, is referred to as DESAT. The region RG11 is called a linear region. The region RG12 is called a saturated region.

Note that a case where the power device PT is a P-type power MOSFET is similar to a case where the power device PT is the N-type power MOSFET, excluding that a voltage between the gate G and the source S that causes the ON state has a reverse polarity, and a drain current flows in a direction from the source S to the drain D.

In a case where the power device PT is a bipolar transistor, one end of the power device PT is a collector C, another end is an emitter, and a control terminal is a base, but this is not illustrated. A transition from a region of a steep current between both ends to a region of a gentle current between both ends is referred to as DESAT.

Hereinafter, a case where the power device PT is the N-type power MOSFET will be principally described. One end, another end, and a control terminal of the power device PT are respectively expressed as D, S, and G. The description below can also be applied to a case where the power device PT is of another type.

The semiconductor device 1 illustrated in FIG. 1 includes input nodes 1a to 1e and an output node if. The node 1a is connected to an outside (for example, a host controller), and receives an input signal IN from the outside. The input node 1b is connected to one end D of a power transistor PT and one end of the load LD. The input node 1c is connected to a control terminal G of the power transistor PT. The input nodes 1d and 1e are respectively connected to one end and another end of a temperature sensor TS. The output node if is connected to the control terminal G of the power transistor PT through resistor RG.

In the power device PT, the one end D is connected to the input node 1b of the semiconductor device 1 and the one end of the load LD, another end S is connected to a ground potential, and the control terminal G is connected to the input node 1c and one side of the resistor RG of the semiconductor device 1. The power device PT may include a rectifying element (for example, a diode) in which a direction from the other end S to the one end D is a forward direction.

At least a portion of the temperature sensor TS is disposed near the power device PT, and the temperature sensor TS can detect the temperature of the power device PT. The temperature sensor TS outputs a detection result to the input nodes 1d and 1e through filter circuit.

The semiconductor device 1 includes a semiconductor integrated circuit 2, a rectifying element D_{DESAT}, a capacitive element C_{BLANK}, a resistor element R_{DESAT}, and a resistor element R_{G}.

The semiconductor integrated circuit 2 may be constituted by a single chip, or may be constituted by plural divided chips. The semiconductor integrated circuit 2 is provided with a terminal IN, a terminal DESAT, a terminal DRV, a terminal GATE, a terminal TEMP, and a terminal GND. The terminal GND is connected to the ground potential.

The rectifying element D_{DESAT} is connected between the terminal DESAT and the one end D of the power device PT. In the rectifying element D_{DESAT}, a direction from the terminal DESAT to the one end D is a forward direction. The rectifying element D_{DESAT} may be a diode.

In the capacitive element C_{BLANK}, one end is connected to a node between the terminal DESAT and the rectifying element D_{DESAT}, and another end is connected to the ground potential. A capacitance value of the capacitive element C_{BLANK} can be determined in advance in accordance with operation characteristics required for a protection circuit 3. The capacitance value of the capacitive element C_{BLANK} can be determined in advance in accordance with charging characteristics (for example, an RC time constant or the charging time using a current source 32) of the capacitive element C_{BLANK} that are required for DESAT detection of the power device PT.

The resistor element R_{DESAT} is connected between the terminal DESAT and the rectifying element D_{DESAT}. A resistance value of the resistor element R_{DESAT} can be determined in advance in accordance with operation characteristics required for the protection circuit 3. The resistance value of the resistor element R_{DESAT} can be determined in advance in accordance with charging characteristics (for example, the RC time constant) of the capacitive element C_{BLANK} that are required for DESAT detection of the power device PT.

The resistor element R_{G} is connected between the terminal DRV and the control terminal G of the power device PT. A resistance value of the resistor element R_{G} can be determined in advance in accordance with operation characteristics (for example, drive capacity) required for a driving circuit 5.

The semiconductor integrated circuit 2 includes the protection circuit 3, a temperature compensation circuit 4, and the driving circuit 5.

The protection circuit 3 is connected between the driving circuit 5 and the terminal DESAT. When the protection circuit 3 has detected DESAT of the power device PT via the terminal DESAT, the protection circuit 3 supplies the driving circuit 5 with a signal Shutdown providing an instruction to shut down the power device PT.

The protection circuit 3 includes a comparator circuit 31, the current source 32, a switch 33, a signal generation circuit 34, and a signal generation circuit 35. The comparator circuit 31 includes an input node 31a, an input node 31b, and an output node 31c. The input node 31a is connected to the one end D of the power transistor PT via the terminal DESAT, the resistor element R_{DESAT}, and the rectifying element D_{DESAT}. The input node 31b is connected to a portion of the temperature compensation circuit 4. For example, the variable voltage source 422 described later is connected to the input node 31b. The variable voltage source 422 generates a threshold voltage Vth in response to a control signal Threshold, and supplies the threshold voltage Vth to the input node 31b. The output node 31c is connected to the signal generation circuit 34.

For example, the comparator circuit 31 compares a voltage V_{DESAT} of the terminal DESAT with the threshold voltage Vth.

In a case where the input node 31a is a non-inverting input node, and the input node 31b is an inverting input node, the comparator circuit 31 outputs a comparison result of an H level if the voltage V_{DESAT} is higher than the threshold voltage Vth, and outputs a comparison result of an L level if the voltage V_{DESAT} is lower than the threshold voltage Vth.

In a case where the input node 31a is the inverting input node, and the input node 31b is the non-inverting input node, the comparator circuit 31 outputs a comparison result of the L level if the voltage V_{DESAT} is higher than the threshold voltage Vth, and outputs a comparison result of the H level if the voltage V_{DESAT} is lower than the threshold voltage Vth.

In the current source 32, one end is connected to a power supply potential, and another end is connected to a node between the input node 31a of the comparator circuit 31 and the terminal DESAT. The current source 32 may be a constant current source, and can supply a constant current to the capacitive element C_{BLANK} via the terminal DESAT. The constant current to be supplied by the current source 32 can be determined in advance in accordance with operation characteristics required for the protection circuit 3. The constant current to be supplied by the current source 32 can be determined in advance in accordance with charging characteristics (for example, the RC time constant) of the capacitive element C_{BLANK} that are required for DESAT detection of the power device PT.

The switch 33 is connected between the one end of the capacitive element C_{BLANK} and the ground potential. In the switch 33, one end is connected to a node between the input node 31a of the comparator circuit 31 and the terminal DESAT, another end is connected to the ground potential, and a control terminal is connected to the signal generation circuit 35.

When the switch 33 has received a control signal MASK of a non-active level (for example, the L level) from the signal generation circuit 35, the switch 33 is turned off to cut off the one end of the capacitive element C_{BLANK} from the ground potential, and bring the capacitive element C_{BLANK} into a chargeable state. When the switch 33 has received a control signal MASK of an active level (for example, the H level) from the signal generation circuit 35, the switch 33 is turned on to connect the one end of the capacitive element C_{BLANK} to the ground potential, extract electric charges from the one end of the capacitive element C_{BLANK}, and discharge into the ground potential.

The signal generation circuit 34 is connected between the comparator circuit 31 and the driving circuit 5. The signal generation circuit 34 generates a control signal Shutdown that shuts down the driving circuit 5, in response to inversion of a comparison result of the comparator circuit 31, and supplies the control signal Shutdown to the driving circuit 5.

In a case where the input node 31a of the comparator circuit 31 is the non-inverting input node, and the input node 31b is the inverting input node, the signal generation circuit 34 supplies the driving circuit 5 with a control signal Shutdown of the non-active level during a period TP1 when the comparator circuit 31 outputs a comparison result of the L level. The signal generation circuit 34 supplies the driving circuit 5 with a control signal Shutdown of the active level during a period TP2 when the comparator circuit 31 outputs a comparison result of the H level.

In a case where the input node 31a of the comparator circuit 31 is the inverting input node, and the input node 31b is the non-inverting input node, the signal generation circuit 34 supplies the protection circuit 3 with a control signal Shutdown of the non-active level during a period TP11 when the comparator circuit 31 outputs a comparison result of the H level. The signal generation circuit 34 supplies the driving circuit 5 with a control signal Shutdown of the active level during a period TP12 when the comparator circuit 31 outputs a comparison result of the L level.

The signal generation circuit 35 is connected between the terminal IN and the switch 33. The signal generation circuit 35 generates a control signal MASK in response to the input signal IN, and supplies the control signal MASK to the switch 33.

The driving circuit 5 includes an input node 5a, an output node 5b, and a control node 5c. The input node 5a is connected to the terminal IN. The output node 5b is connected to the control terminal G of the power transistor PT via the terminal DRV and the resistor element R_{G}. The control node 5c is connected to the protection circuit 3.

The driving circuit 5 is connected between the terminal IN and the terminal DRV. While the driving circuit 5 is receiving the control signal Shutdown of the non-active level, the driving circuit 5 generates a driving signal DRV that causes switching in response to the input signal IN, and supplies the driving signal DRV to the control terminal G of the power transistor PT. As a result of this, switching control can be performed on the power transistor PT.

When the driving circuit 5 has received the control signal Shutdown of the active level, the driving circuit 5 generates a driving signal DRV that causes an OFF state to be maintained regardless of the input signal IN, and supplies the driving signal DRV to the control terminal G of the power transistor PT. As a result of this, the power transistor PT is maintained in the OFF state. This enables the power transistor PT to be protected against overcurrent that occurs in the load LD.

The temperature compensation circuit 4 is connected between the terminal GATE and the terminal TEMP, and the protection circuit 3. The temperature compensation circuit 4 includes a correction circuit 41 and a voltage supply circuit 42. The correction circuit 41 is disposed between the terminal GATE and the terminal TEMP, and the voltage supply circuit 42. The voltage supply circuit 42 is disposed between the correction circuit 41 and the protection circuit 3.

The correction circuit 41 generates a correction signal that corresponds to the temperature of the power device PT and the voltage V_{G} of the control terminal G. The voltage supply circuit 42 corrects the threshold voltage Vth in response to the correction signal. The voltage supply circuit 42 supplies the corrected threshold voltage Vth to the input node 31b of the comparator circuit 31.

The correction circuit 41 includes an input node 41a, an input node 41b, and an output node 41c. The input node 41a is connected to the temperature sensor TS via the terminal TEMP. One end of a current source 7 may be connected between the input node 41a and the terminal TEMP. Another end of the current source 7 may be connected to the power supply potential. The input node 41b is connected to the control terminal G of the power transistor PT via the terminal GATE. The output node 41c is connected to the voltage supply circuit 42.

The correction circuit 41 includes a temperature acquisition circuit 411, a voltage acquisition circuit 412, and a correction processing circuit 413. The temperature acquisition circuit 411 is connected between the terminal TEMP and the correction processing circuit 413. The voltage acquisition circuit 412 is connected between the terminal GATE and the correction processing circuit 413. The correction processing circuit 413 is connected between the temperature acquisition circuit 411 and the voltage acquisition circuit 412, and the voltage supply circuit 42.

In the correction circuit 41, the temperature acquisition circuit 411 acquires a signal indicating the temperature of the power device PT from the temperature sensor TS via the terminal TEMP and the input node 41a. The temperature acquisition circuit 411 converts a format of the signal into a format that can be processed by the correction processing circuit 413, and supplies the signal after conversion to the correction processing circuit 413.

The voltage acquisition circuit 412 acquires a signal indicating a voltage of the control terminal G from the control terminal G of the power device PT via the terminal GATE and the input node 41b. The voltage acquisition circuit 412 converts a format of the signal into a format that can be processed by the correction processing circuit 413, and supplies the signal after conversion to the correction processing circuit 413.

The correction circuit 41 receives the signal from the temperature acquisition circuit 411, and receives the signal from the voltage acquisition circuit 412. The correction circuit 41 generates a correction signal that corresponds to the temperature of the power device PT and the voltage of the control terminal G, and supplies the correction signal to the voltage supply circuit 42 via the output node 41c.

The voltage supply circuit 42 includes an input node 42a and an output node 42b. The input node 42a is connected to the correction circuit 41. The output node 42b is connected to the input node 31b of the comparator circuit 31.

The voltage supply circuit 42 includes a control circuit 421 and a variable voltage source 422. The control circuit 421 is connected between the correction processing circuit 413 and the variable voltage source 422. In the variable voltage source 422, one end is connected to the input node 31b of the comparator circuit 31, another end is connected to the ground potential, and a control terminal is connected to the control circuit 421.

In the voltage supply circuit 42, the control circuit 421 receives the correction signal from the correction circuit 41. The control circuit 421 corrects the threshold voltage Vth in response to the correction signal. The voltage supply circuit 42 generates a control signal Threshold that provides an instruction about the corrected threshold voltage Vth, and supplies the control signal Threshold to a control node of the variable voltage source 422. The variable voltage source 422 regulates a voltage to be generated in response to the control signal Threshold, and supplies the regulated voltage as the threshold voltage Vth to the input node 31b of the comparator circuit 31.

For example, in a case where the temperature of the power device PT is a first temperature, and the voltage of the control terminal G is a first voltage, the correction circuit 41 generates a first correction signal. The first correction signal includes an instruction to correct a level of the threshold voltage to a first level. The first level may correspond to a rated current of the power device PT at the first temperature. The correction circuit 41 supplies the first correction signal to the voltage supply circuit 42. The voltage supply circuit 42 corrects a level of the threshold voltage Vth to the first level in response to the first correction signal.

Alternatively, in a case where the temperature of the power device PT is a second temperature, and the voltage of the control terminal G is a first voltage, the correction circuit 41 generates a second correction signal. The second temperature is higher than the first temperature. The second correction signal includes an instruction to correct a level of the threshold voltage Vth to a second level. The second level is lower than the first level. The second level may correspond to a rated current of the power device at the second temperature. The correction circuit 41 supplies the second correction signal to the voltage supply circuit 42. The voltage supply circuit 42 corrects the level of the threshold voltage Vth to the second level in response to the second correction signal.

By doing this, in the semiconductor device 1, DESAT detection of the power device PT can be performed by using a threshold voltage Vth that corresponds to temperature and the voltage of the control terminal G while a current margin of the power device PT is secured.

Note that a configuration that includes the signal generation circuit 34, the signal generation circuit 35, and the control circuit 421 can be regarded as a DESAT processing circuit 6 that performs processing relating to DESAT. Furthermore, the semiconductor integrated circuit 2 may further include a control circuit 8 that can supply a control signal to each of the temperature acquisition circuit 411 and the voltage acquisition circuit 412.

As the temperature sensor TS illustrated in FIG. 1, an arbitrary temperature sensor that can measure temperature is used. The temperature sensor TS may be configured as illustrated in FIG. 3. FIG. 3 is a circuit diagram illustrating a configuration of the temperature sensor TS.

The temperature sensor TS includes a sensor element SE and a filter circuit FC. The sensor element SE may be disposed near the power device PT. The sensor element SE includes a thermistor TH. The thermistor TH may be an NTC thermistor, or may be a PTC thermistor. A resistance value of the thermistor TH changes depending on temperature.

The filter circuit FC is connected between the sensor element SE and the semiconductor device 1. The filter circuit FC includes resistor elements R_{FL1} and R_{FL2}, a filter FL, and a capacitive element C_{FL}. In the resistor element R_{FL1}, one end is connected to one end of the thermistor TH, and another end is connected to another end of the thermistor TH. In the resistor element R_{FL2}, one end is connected to the other end of the thermistor TH, and another end is connected to the ground potential. The filter FL is connected between the capacitive element C_{FL} and the resistor elements R_{FL1} and R_{FL2}. The filter FL may be a low-pass filter. In the capacitive element C_{FL}, one end is connected to the input node 1d of the semiconductor device 1 and a P side node of the filter FL, and another end is connected to the input node 1e of the semiconductor device 1 and an N side node of the filter FL.

The filter circuit FC can perform filtering processing on a detection signal of the sensor element SE, and can supply the detection signal after processing to the semiconductor device 1. The filter circuit FC receives a voltage across the sensor element SE at a pair of input nodes, and outputs a pair of detection signals (a P side detection signal and an N side detection signal) that correspond to the voltage across the sensor element SE from a pair of output nodes to the input nodes 1d and 1e.

In accordance with a change in the resistance value of the thermistor TH depending on temperature, respective amounts of currents that flow from the current source 7 via the terminal TEMP and the filter FL into the thermistor TH and the resistor elements R_{FL1} and R_{FL2} change. Voltages generated across the resistor elements R_{FL1} and R_{FL2} change depending on temperature. The voltages are smoothed by the filter FL and the capacitive element C_{FL}, and are transmitted as the pair of detection signals (the P side detection signal and the N side detection signal) via the input nodes 1d and 1e to the terminal TEMP and the terminal GND. The P side detection signal flows via the terminal TEMP to the temperature compensation circuit 4, and the N side detection signal flows via the terminal GND to the ground potential.

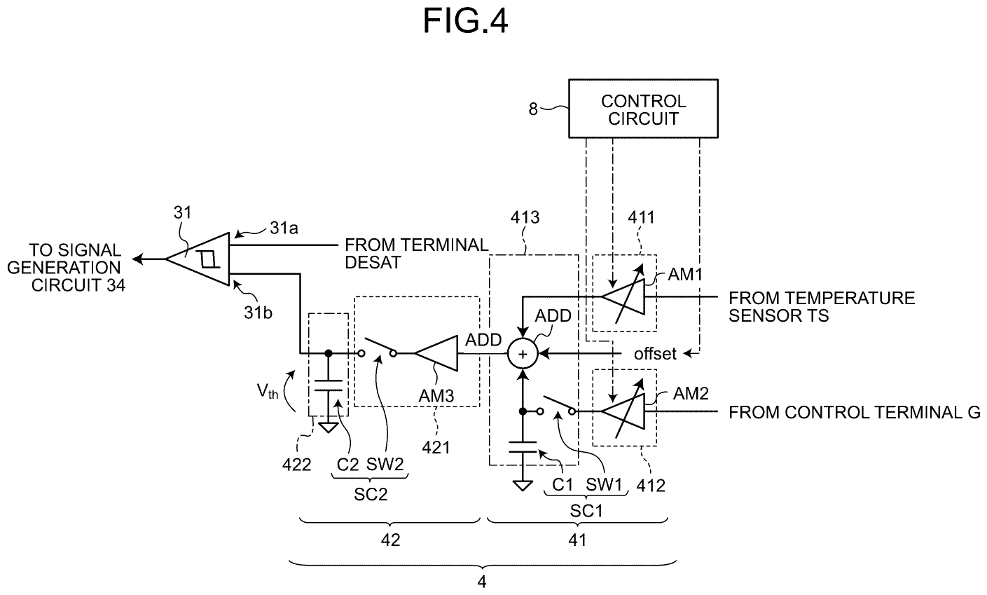

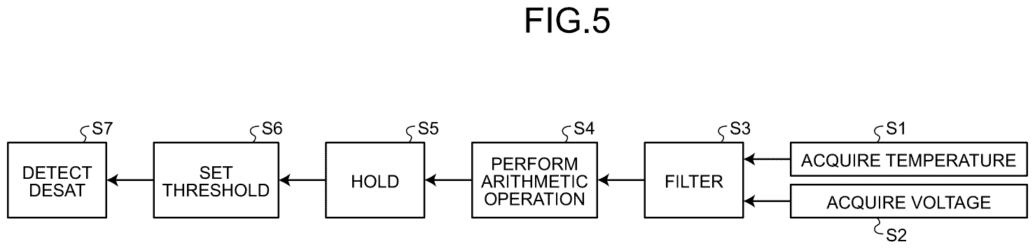

The temperature compensation circuit 4 illustrated in FIG. 1 may be configured as illustrated in FIG. 4, and may operate as illustrated in FIG. 5. FIG. 4 is a circuit diagram illustrating a configuration of the temperature compensation circuit 4. FIG. 5 is a sequence diagram illustrating an operation of the temperature compensation circuit 4.

In the correction circuit 41 of the temperature compensation circuit 4, the temperature acquisition circuit 411 includes a variable amplifier AM1. The voltage acquisition circuit 412 includes a variable amplifier AM2. The correction processing circuit 413 includes an adder ADD, a switch SW1, and a capacitive element C1.

In the variable amplifier AM1, an input node is connected to the temperature sensor TS, and an output node is connected to the adder ADD. In the variable amplifier AM1, a gain is variable. In the variable amplifier AM1, the gain may be adjusted in advance under the control of the control circuit 8 at the time of calibration. A value of the gain to be adjusted can be experimentally determined in advance.

The variable amplifier AM1 acquires a signal indicating the temperature of the power device PT from the temperature sensor TS (S1). The variable amplifier AM1 amplifies the signal by using the gain to convert a format of the signal into a format that can be processed by the correction processing circuit 413, and supplies a signal AM1 after conversion to the correction processing circuit 413.

In the variable amplifier AM2, an input node is connected to the control terminal G of the power device PT, and an output node is connected to the adder ADD via the switch SW. In the variable amplifier AM2, a gain is variable. In the variable amplifier AM2, the gain may be adjusted in advance under the control of the control circuit 8 at the time of calibration. A value of the gain to be adjusted can be experimentally determined in advance.

The variable amplifier AM2 acquires a signal indicating the voltage of the control terminal G from the control terminal G of the power device PT (S2). The variable amplifier AM2 amplifies the signal by using the gain to convert a format of the signal into a format that can be processed by the correction processing circuit 413, and supplies a signal AM2 after conversion to the correction processing circuit 413.

In the switch SW1, one end is connected to the variable amplifier AM2, and another end is connected to one end of the capacitive element C1 and the adder ADD. Another end of the capacitive element C1 is connected to the ground potential.

The switch SW1 may be maintained in the ON state and the OFF state in predetermined periods. During a period when the switch SW1 is maintained in the ON state, the signal AM2 after amplification performed by the variable amplifier AM2 is sampled and is transmitted to the capacitive element C1, and during a period when the switch SW1 is maintained in the OFF state, the signal AM2 after amplification is held in the capacitive element C1. By doing this, a switched capacitor SC1 including the switch SW1 and the capacitive element C1 equivalently operates as a filter (S3) to be able to reduce noise in the signal AM2 after amplification performed by the variable amplifier AM2, and generate a signal AM2a after filter processing.

The adder ADD receives the signal AM1 after amplification from the variable amplifier AM1, receives the signal AM2a after filter processing from the switched capacitor SC1, and receives a signal offset from the control circuit 8. The signal offset can be experimentally determined in advance. The adder ADD adds the signal AM1, the signal AM2a, and the signal offset. Stated another way, the adder ADD performs an arithmetic operation to generate a correction signal ADD that corresponds to the signal AM1, the signal AM2a, and the signal offset (S4), and supplies the correction signal ADD to the voltage supply circuit 42.

In the voltage supply circuit 42, the control circuit 421 includes an amplifier AM3 and a switch SW2. The variable voltage source 422 includes a capacitive element C2.

In the amplifier AM3, an input node is connected to the adder ADD, and an output node is connected to the switch SW2. In the switch SW2, one end is connected to the amplifier AM3, and another end is connected to one end of the capacitive element C2. Another end of the capacitive element C2 is connected to the ground potential.

The amplifier AM3 receives the correction signal ADD from the adder ADD. The amplifier AM3 amplifies the correction signal ADD, and supplies the correction signal ADD to a side of the switch SW2.

The switch SW2 may be maintained in the ON state and the OFF state in predetermined periods. During a period when the switch SW2 is maintained in the ON state, a signal AM3 after amplification performed by the amplifier AM3 is sampled and is transmitted to the capacitive element C2, and during a period when the switch SW2 is maintained in the OFF state, the signal AM3 after amplification is held in the capacitive element C2. Stated another way, the signal AM3 that corresponds to the correction signal ADD is held in the capacitive element C2 (S5). By doing this, a switched capacitor SC2 including the switch SW2 and the capacitive element C2 equivalently operates as a filter to be able to reduce noise in the signal AM3 after amplification performed by the amplifier AM3, and generate a signal AM3a after filter processing. In response to this signal AM3a after filter processing, the capacitive element C2 generates a threshold voltage Vth across the capacitive element C2, and transmits the threshold voltage Vth to the input node 31b of the comparator circuit 31. Stated another way, the capacitive element C2 sets, for the input node 31b of the comparator circuit 31, the threshold voltage Vth that corresponds to the correction signal ADD (S6). In response to this, the protection circuit 3 including the comparator circuit 31 can perform DESAT detection, by using the threshold voltage Vth that corresponds to the correction signal ADD (S7).

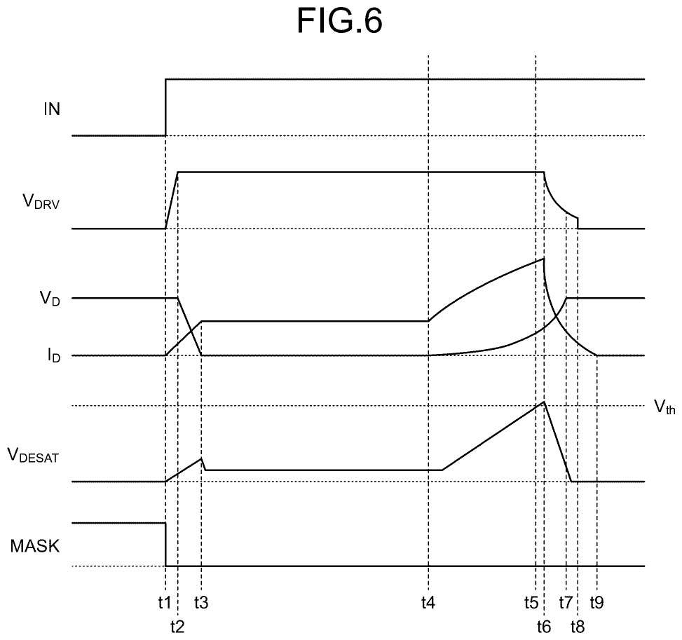

Next, a time-series operation of the semiconductor device 1 will be described with reference to FIG. 6. FIG. 6 is a waveform diagram illustrating an operation of the semiconductor device 1.

Immediately before timing t1, the protection circuit 3 sets the control signal MASK to the active level, and maintains the switch 33 in the ON state. This invalidates DESAT detection performed by the protection circuit 3.

When a rise of a waveform of the input signal INPUT has been detected at timing t1, the driving circuit 5 sets a driving signal V_{DRV} to the active level.

When the driving signal V_{DRV} has reached the active level (for example, the H level) at timing t2, the voltage V_{G} of the control terminal G starts to rise, and in response to this, the power device PT starts to be in the ON state. In response to this, the current I_{D} starts to flow through the power device PT, and the voltage V_{D} of the one end D starts to fall.

The protection circuit 3 sets the control signal MASK to the non-active level, and turns off the switch 33. In response to this, in the protection circuit 3, DESAT detection is validated. Stated another way, the protection circuit 3 enters into a state where DESAT of the power device PT can be detected.

At timing t3, the current I_{D} becomes stable at a predetermined level, the voltage V_{D} of the one end D falls to a reference level (for example, the L level), and a transition to the ON state of the power device PT has been completed.

Note that during a period from timing t1 to timing t3, the voltage V_{DESAT} of the terminal DESAT can temporarily rise, but the voltage V_{DESAT} is lower than the threshold voltage Vth. Therefore, the protection circuit 3 does not detect a temporary rise in the voltage V_{DESAT} as DESAT.

When an excessive current I_{D} has started to flow into the power device PT having the ON state due to a short circuit or the like of the load LD at timing t4, the voltage V_{D} of the one end D suddenly starts to rise, and in response to this, the voltage V_{DESAT} of the terminal DESAT also suddenly starts to rise.

When the voltage V_{DESAT} of the terminal DESAT has become higher than the threshold voltage Vth at timing t5, a comparison result of the comparator circuit 31 is inverted. Stated another way, the protection circuit 3 detects DESAT of the power device PT.

In response to this, at timing t6, the protection circuit 3 transitions the control signal Shutdown to the active level, and supplies the control signal Shutdown to the driving circuit 5. The driving circuit 5 transitions the driving signal V_{DRV} to the non-active level (for example, the L level). In response to this, the power device PT starts to be in the OFF state, the current I_{D} starts to decrease, and the voltage V_{D} of the one end D continues to rise.

At timing t7, the voltage V_{D} of the one end D has reached a predetermined level (for example, the H level) and is maintained at the predetermined level, and the driving signal V_{DRV} falls to nearly a reference level (for example, the L level). As a result of this, OFF control is performed on the power device PT.

At timing t8, the driving signal V_{DRV} has completed a transition to the non-active level (for example, the L level), at timing t9, the current I_{D} that flows into the one end D of the power device PT falls to a reference level, and a transition to the OFF state of the power device PT has been completed.

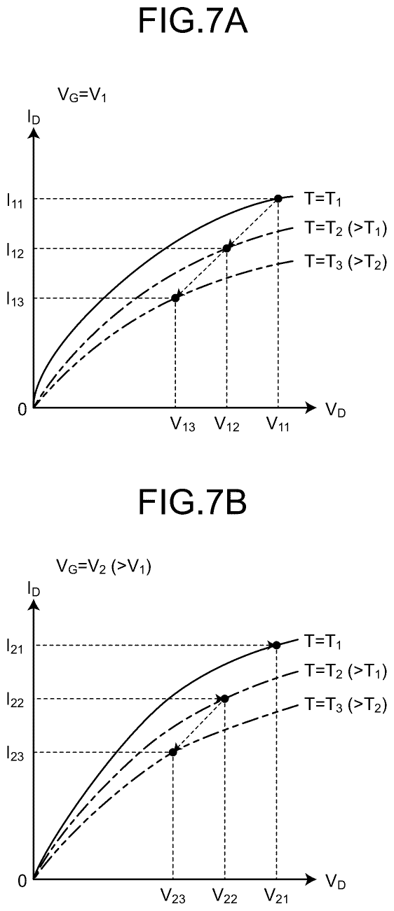

Next, an operation of the temperature compensation circuit 4 will be described with reference to FIGS. 7A and 7B. FIGS. 7A and 7B are diagrams illustrating the operation of the temperature compensation circuit 4.

In the temperature compensation circuit 4, the correction circuit 41 generates a correction signal that corresponds to the temperature T of the power device PT and the voltage V_{G} of the control terminal G. The correction circuit 41 may generate, for each of the voltages V_{G}, a correction signal that provides an instruction of correction to a threshold voltage Vth that corresponds to a rated current of the power device PT at the temperature T.

For example, in a case where voltage V_{G}=V₁, a relationship between a voltage V_{D} across the power transistor PT and the current I_{D} is as illustrated in FIG. 7A. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that rated current I_{D}=I₁₁, I₁₂, and I₁₃, respectively, in a case where temperature T=T₁, T₂, and T₃. The rated current can be differently described as an upper limit value of an allowable current at a given temperature. In a case where temperature T=T₁, T₂, and T₃, respective voltages V_{D} (V_{D}=V₁₁, V₁₂, and V₁₃) in a case where current I_{D}=I₁₁, I₁₂, and I₁₃ may be set as a correction target level of the threshold voltage. V₁₁, V₁₂, and V₁₃ decrease in this order.

The correction circuit 41 generates a correction signal including an instruction to correct a level of the threshold voltage to level V₁₁ in a case where (T, V_{G})=(T₁, V₁), and supplies the correction signal to the voltage supply circuit 42. The voltage supply circuit 42 corrects the level of the threshold voltage Vth to level V₁₁ in response to the correction signal, and supplies the threshold voltage Vth to the input node 31b of the comparator circuit 31.

The correction circuit 41 generates a correction signal including an instruction to correct the level of the threshold voltage to level V₁₂ in a case where (T, V_{G})=(T₂, V₁), and supplies the correction signal to the voltage supply circuit 42. The voltage supply circuit 42 corrects the level of the threshold voltage Vth to level V₁₂ in response to the correction signal, and supplies the threshold voltage Vth to the input node 31b of the comparator circuit 31.

The correction circuit 41 generates a correction signal including an instruction to correct the level of the threshold voltage to level V₁₃ in a case where (T, V_{G})=(T₃, V₁), and supplies the correction signal to the voltage supply circuit 42. The voltage supply circuit 42 corrects the level of the threshold voltage Vth to level V₁₃ in response to the correction signal, and supplies the threshold voltage Vth to the input node 31b of the comparator circuit 31.

As another example, in a case where voltage V_{G}=V₂ (>V₁), a relationship between the voltage VD across the power transistor PT and the current I_{D} is as illustrated in FIG. 7B. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that rated current I_{D}=I₂₁, I₂₂, and I₂₃, respectively, in a case where temperature T=T₁, T₂, and T₃. The rated current can be differently described as an upper limit value of an allowable current at a given temperature. In a case where temperature T=T₁, T₂, and T₃, respective voltages V_{D} (V_{D}=V₂₁, V₂₂, and V₂₃) in a case where current I_{D}=I₂₁, I₂₂, and I₂₃ may be set as a correction target level of the threshold voltage. V₂₁, V₂₂, and V₂₃ decrease in this order.

The correction circuit 41 generates a correction signal including an instruction to correct the level of the threshold voltage to level V₂₁ in a case where (T, V_{G})=(T₁, V₂), and supplies the correction signal to the voltage supply circuit 42. The voltage supply circuit 42 corrects the threshold voltage Vth to level V₂₁ in response to the correction signal, and supplies the threshold voltage Vth to the input node 31b of the comparator circuit 31.

The correction circuit 41 generates a correction signal including an instruction to correct the level of the threshold voltage to level V₂₂ in a case where (T, V_{G})=(T₂, V₂), and supplies the correction signal to the voltage supply circuit 42. The voltage supply circuit 42 corrects the level of the threshold voltage Vth to level V₂₂ in response to the correction signal, and supplies the threshold voltage Vth to the input node 31b of the comparator circuit 31.

The correction circuit 41 generates a correction signal including an instruction to correct the level of the threshold voltage to level V₂₃ in a case where (T, V_{G})=(T₃, V₂), and supplies the correction signal to the voltage supply circuit 42. The voltage supply circuit 42 corrects the level of the threshold voltage Vth to level V₂₃ in response to the correction signal, and supplies the threshold voltage Vth to the input node 31b of the comparator circuit 31.

Note that in a case where the temperature compensation circuit 4 is configured as illustrated in FIG. 4, the control circuit 8 may set a gain that corresponds to an increase T₁->T₂->T₃ in a signal of the temperature T for the variable amplifier AM1, and may set a gain that corresponds to an increase V₁->V₂ of a signal of the voltage V_{G} for the variable amplifier AM2.

As described above, in the present embodiment, in the temperature compensation circuit 4 of the semiconductor device 1, the correction circuit 41 generates a correction signal that corresponds to the temperature T of the power device PT and the voltage V_{G} of the control terminal G. The voltage supply circuit 42 may correct the threshold voltage Vth in response to the correction signal. The voltage supply circuit 42 may supply the corrected threshold voltage Vth to the input node 31b of the comparator circuit 31. This enables the protection circuit 3 including the comparator circuit 31 to perform DESAT detection by using an appropriate threshold voltage Vth that corresponds to the temperature T of the power device PT and the voltage V_{G} of the control terminal G.

Furthermore, in the present embodiment, in the temperature compensation circuit 4 of the semiconductor device 1, the correction circuit 41 can generate a correction signal that provides an instruction of correction to a lower level according to an increase in the temperature of the power device PT, if the control terminal G has an identical voltage. The voltage supply circuit 42 may correct the level of the threshold voltage Vth to an instructed level in response to the correction signal. By doing this, in the semiconductor device 1, DESAT detection of the power device PT can be performed by using a threshold voltage Vth that corresponds to the temperature T and the voltage V_{G} of the control terminal G while a current margin of the power device PT is secured.

### First Variation of Embodiment

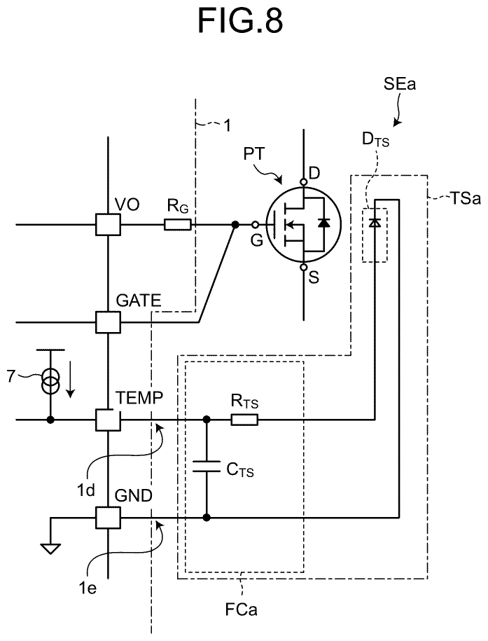

Note that the temperature sensor TS may be configured as illustrated in FIG. 8. FIG. 8 is a circuit diagram illustrating a configuration of a temperature sensor TSa according to a first variation of the embodiment.

The temperature sensor TSa includes a sensor element SEa and a filter circuit FCa. The sensor element SEa may be disposed near the power device PT. The sensor element SEa includes a diode D_{TS}. In the diode D_{TS}, a forward voltage changes depending on temperature.

The filter circuit FC is connected between the sensor element SEa and the semiconductor device 1. The filter circuit FC includes a resistor element R_{T}s and a capacitive element C_{TS}. In the resistor element R_{TS}, one end is connected to one end of the diode D_{TS}, and another end is connected to the input node 1d of the semiconductor device 1. In the capacitive element C_{TS}, one end is connected to the input node 1d of the semiconductor device 1 and the one end of the resistor element R_{TS}, and another end is connected to the input node 1e of the semiconductor device 1 and one end of the diode D_{TS}

The filter circuit FCa can perform filtering processing on a detection signal of the sensor element SEa, and can supply the detection signal after processing to the semiconductor device 1. The filter circuit FCa receives a voltage across the sensor element SEa at a pair of input nodes, and outputs a pair of detection signals (a P side detection signal and an N side detection signal) that correspond to the voltage across the sensor element SEa from a pair of output nodes to the input nodes 1d and 1e.

In accordance with a change in the forward voltage of the diode D_{T}s depending on temperature, a voltage across the diode D_{TS} from the current source 7 via the terminal TEMP and the resistor element R_{TS} changes. The voltage is smoothed by the filter FL, and is transmitted as a pair of detection signals (the P side detection signal and the N side detection signal) via the input nodes 1d and 1e to the terminal TEMP and the terminal GND. The P side detection signal flows via the terminal TEMP to the temperature compensation circuit 4, and the N side detection signal flows via the terminal GND to the ground potential.

By employing the temperature sensor TSa, as above, the temperature of the power device PT can be measured similarly.

### Second Variation of Embodiment

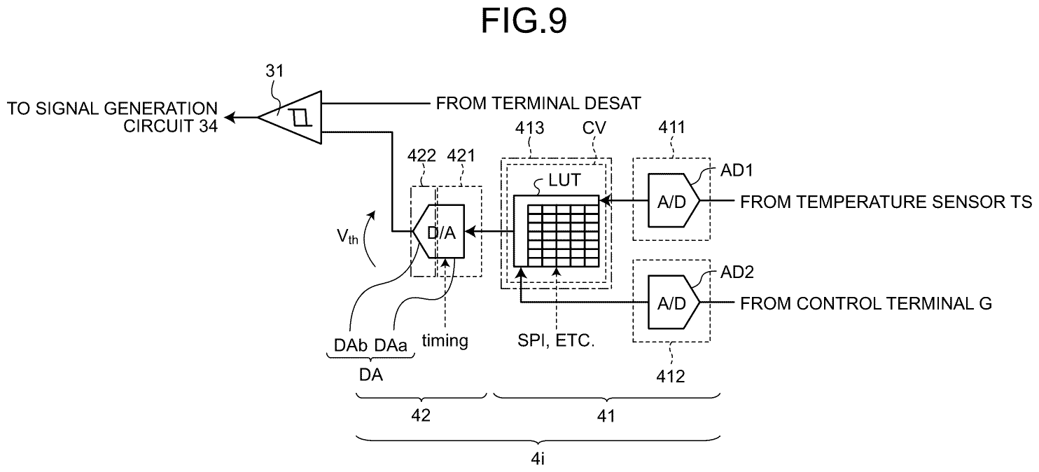

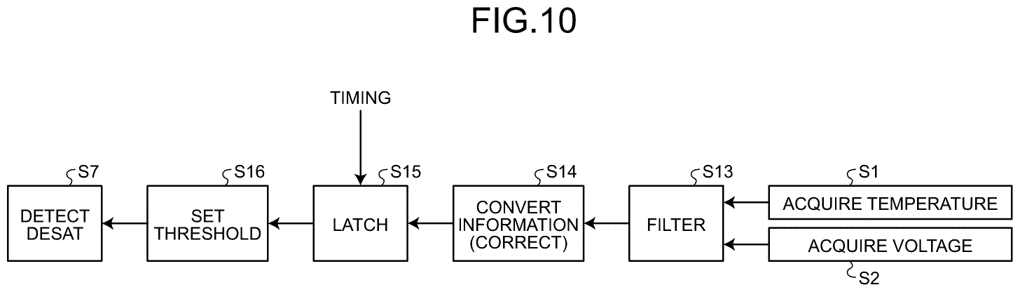

A temperature compensation circuit 4i may be configured as illustrated in FIG. 9, and may operate as illustrated in FIG. 10. FIG. 9 is a circuit diagram illustrating a configuration of the temperature compensation circuit 4i according to a second variation of the embodiment. FIG. 10 is a sequence diagram illustrating an operation of the temperature compensation circuit 4i.

In the correction circuit 41 of the temperature compensation circuit 4i, the temperature acquisition circuit 411 includes an AD conversion circuit AD1. The voltage acquisition circuit 412 includes an AD conversion circuit AD2. The correction processing circuit 413 includes an information conversion circuit CV. The information conversion circuit CV holds correction information LUT. The correction information LUT is information in which the temperature T, the voltage V_{G} of the control terminal G, and the threshold voltage Vth have been associated with each other for a plurality of combinations of the temperature T and the voltage V_{G} of the control terminal G.

In the AD conversion circuit AD1, an input node is connected to the temperature sensor TS, and an output node is connected to the information conversion circuit CV.

The AD conversion circuit AD1 acquires a signal indicating the temperature of the power device PT from the temperature sensor TS (S1). The AD conversion circuit AD1 performs AD conversion on the signal (an analog signal) to convert a format of the signal into a format that the correction processing circuit 413 can process, and supplies a signal AD1 after conversion (a digital signal) to the correction processing circuit 413.

In the AD conversion circuit AD2, an input node is connected to the control terminal G of the power device PT, and an output node is connected to the information conversion circuit CV.

The AD conversion circuit AD2 acquires a signal indicating the voltage of the control terminal G from the control terminal G of the power device PT (S2). The AD conversion circuit AD2 performs AD conversion on the signal (an analog signal) to convert a format of the signal into a format that the correction processing circuit 413 can process, and supplies a signal AD1 after conversion (a digital signal) to the correction processing circuit 413.

The information conversion circuit CV receives the signal AD1 after conversion from the AD conversion circuit AD1, and receives the signal AD2 after conversion from the AD conversion circuit AD2. The information conversion circuit CV performs predetermined filter processing on the signal AD1 and the signal AD2 (S13), and acquires a signal AD1a and a signal AD2a after processing.

It should be noted that the information conversion circuit CV may omit the predetermined filter processing and use the received signal AD1 and AD2 as a signal AD1a and a signal AD2a.

The information conversion circuit CV refers to the correction information LUT, and specifies a threshold voltage that corresponds to a temperature indicated by the signal AD1a and a voltage indicated by the signal AD2a.

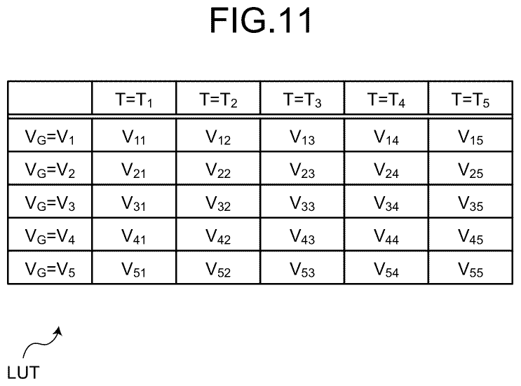

For example, the information conversion circuit CV may refer to the correction information LUT illustrated in FIG. 11. FIG. 11 is a diagram illustrating a data structure of the correction information LUT according to the second variation of the embodiment.

The correction information LUT is information in which the temperature T, the voltage V_{G} of the control terminal G, and the threshold voltage Vth have been associated with each other for a plurality of combinations of the temperature T and the voltage V_{G} of the control terminal G. By referring to the correction information LUT, a threshold voltage in a case where (T, V_{G})=(T₁, V₁) can be specified in such a way that Vth=V₁₁. A threshold voltage in a case where (T, V_{G})=(T₂, V₁) can be specified in such a way that Vth=V₁₂. A threshold voltage in a case where (T, V_{G})=(T₃, V₁) can be specified in such a way that Vth=V₁₃ . . . . A threshold voltage in a case where (T, V_{G})=(T₁, V₂) can be specified in such a way that Vth=V₂₁. A threshold voltage in a case where (T, V_{G})=(T₂, V₂) can be specified in such a way that Vth=V₂₂. A threshold voltage in a case where (T, V_{G})=(T₃, V₂) can be specified in such a way that Vth=V₃₃ . . . . A threshold voltage in a case where (T, V_{G})=(T₅, V₅) can be specified in such a way that Vth=V₅₅.

Stated another way, the information conversion circuit CV performs an arithmetic operation to generate a correction signal LUT that corresponds to the signal AD1 and the signal AD2, by using the correction information LUT (S14), and supplies the correction signal LUT to the voltage supply circuit 42.

The voltage supply circuit 42 includes a DA conversion circuit DA. In the DA conversion circuit DA, a pre-stage portion DAa functions as the control circuit 421, and a post-stage portion DAb functions as the variable voltage source 422.

In the DA conversion circuit DA, an input node is connected to the information conversion circuit CV, and an output node is connected to the input node 31b of the comparator circuit 31.

The DA conversion circuit DA receives the correction signal LUT from the information conversion circuit CV. The DA conversion circuit DA latches the correction signal LUT in synchronization with a timing signal (S15). The DA conversion circuit DA performs DA conversion on the latched correction signal LUT (a digital signal), and transmits a signal after conversion (an analog signal) as the threshold voltage Vth to the input node 31b of the comparator circuit 31. Stated another way, the DA conversion circuit DA sets, for the input node 31b of the comparator circuit 31, the threshold voltage Vth that corresponds to the correction signal LUT (S16). In response to this, the protection circuit 3 including the comparator circuit 31 can perform DESAT detection, by using the threshold voltage Vth that corresponds to the correction signal ADD (S7).

By employing the temperature compensation circuit 4i, as above, similarly, the threshold voltage Vth that corresponds to the temperature T of the power device PT and the voltage V_{G} of the control terminal G can be corrected, and the corrected threshold voltage Vth can be supplied to the input node 31b of the comparator circuit 31.

### Third Variation of Embodiment

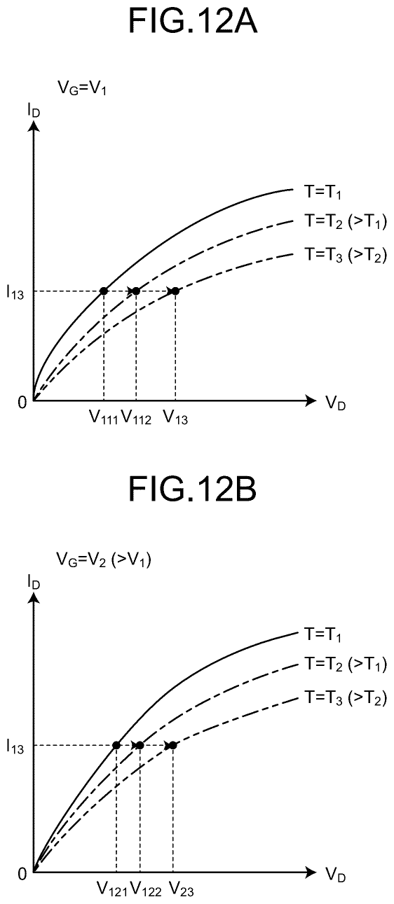

The temperature compensation circuit 4 may operate as illustrated in FIGS. 12A and 12B. FIGS. 12A and 12B are diagrams illustrating an operation of the temperature compensation circuit 4 according to a third variation of the embodiment.

In the temperature compensation circuit 4, the correction circuit 41 generates a correction signal that corresponds to the temperature T of the power device PT and the voltage V_{G} of the control terminal G. The correction circuit 41 may generate, for each of the voltages V_{G}, a correction signal that provides an instruction of correction to a threshold voltage Vth that causes a current of the power device PT to be maintained constant at different temperatures T.

For example, in a case where voltage V_{G}=V₁, a relationship between the voltage V_{D} across the power transistor PT and the current I_{D} is as illustrated in FIG. 12A. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that current I_{D} to be maintained at different temperatures T (T=T₁, T₂, and T₃)=I₁₃. The current to be maintained may be a rated current at a lowest temperature T of the different temperatures T. In a case where temperature T=T₁, T₂, and T₃, respective voltages V_{D}(V_{D}=V₁₁₁, V₁₁₂, and V₁₃) in a case where current I_{D}=I₁₃ may be set as a correction target level of the threshold voltage. V₁₁₁, V₁₁₂, and V₁₃ increase in this order.

The correction circuit 41 generates a correction signal including an instruction to correct the level of the threshold voltage to level V₁₁₁ in a case where (T, V_{G})=(T₁, V₁), and supplies the correction signal to the voltage supply circuit 42. The voltage supply circuit 42 corrects the level of the threshold voltage Vth to level Viii in response to the correction signal, and supplies the threshold voltage Vth to the input node 31b of the comparator circuit 31.

The correction circuit 41 generates a correction signal including an instruction to correct the level of the threshold voltage to level V₁₁₂ in a case where (T, V_{G})=(T₂, V₁), and supplies the correction signal to the voltage supply circuit 42. The voltage supply circuit 42 corrects the level of the threshold voltage Vth to level V₁₁₂ in response to the correction signal, and supplies the threshold voltage Vth to the input node 31b of the comparator circuit 31.

The correction circuit 41 generates a correction signal including an instruction to correct the level of the threshold voltage to level V₁₃ in a case where (T, V_{G})−(T₃, V₁), and supplies the correction signal to the voltage supply circuit 42. The voltage supply circuit 42 corrects the level of the threshold voltage Vth to level V₁₃ in response to the correction signal, and supplies the threshold voltage Vth to the input node 31b of the comparator circuit 31.

As another example, in a case where voltage V_{G}=V₂ (>V₁), a relationship between the voltage V_{D} across the power transistor PT and the current I_{D} is as illustrated in FIG. 12B. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that current I_{D} to be maintained at different temperatures T (T=T₁, T₂, and T₃)=I₂₃. The current to be maintained may be a rated current at a lowest temperature T of the different temperatures T. In a case where temperature T=T₁, T₂, and T₃, respective voltages V_{D}(V_{D}=V₁₂₁, V₁₂₂, and V₂₃) in a case where current I_{D}=I₂₃ may be set as a correction target level of the threshold voltage. V₁₂₁, V₁₂₂, and V₂₃ increase in this order.

The correction circuit 41 generates a correction signal including an instruction to correct the level of the threshold voltage to level V₁₂₁ in a case where (T, V_{G})=(T₁, V₂), and supplies the correction signal to the voltage supply circuit 42. The voltage supply circuit 42 corrects the level of the threshold voltage Vth to level V₁₂₁ in response to the correction signal, and supplies the threshold voltage Vth to the input node 31b of the comparator circuit 31.

The correction circuit 41 generates a correction signal including an instruction to correct the level of the threshold voltage to level V₁₂₂ in a case where (T, V_{G})=(T₂, V₂), and supplies the correction signal to the voltage supply circuit 42. The voltage supply circuit 42 corrects the level of the threshold voltage Vth to level V₁₂₂ in response to the correction signal, and supplies the threshold voltage Vth to the input node 31b of the comparator circuit 31.

The correction circuit 41 generates a correction signal including an instruction to correct the level of the threshold voltage to level V₂₃ in a case where (T, V_{G})=(T₃, V₂), and supplies the correction signal to the voltage supply circuit 42. The voltage supply circuit 42 corrects the level of the threshold voltage Vth to level V₂₃ in response to the correction signal, and supplies the threshold voltage Vth to the input node 31b of the comparator circuit 31.

Note that in a case where the temperature compensation circuit 4 is configured as illustrated in FIG. 4, the control circuit 8 may set a gain that corresponds to an increase T₁->T₂->T₃ in a signal of the temperature T for the variable amplifier AM1, and may set a gain that corresponds to an increase V₁->V₂ of a signal of the voltage V_{G} for the variable amplifier AM2.

An operation of the temperature compensation circuit 4, as above, enables the current I_{D} of the power transistor PT to be maintained constant at different temperatures T, and therefore malfunction of the load LD can be easily analyzed when overcurrent has flowed from the load LD.

### Fourth Variation of Embodiment

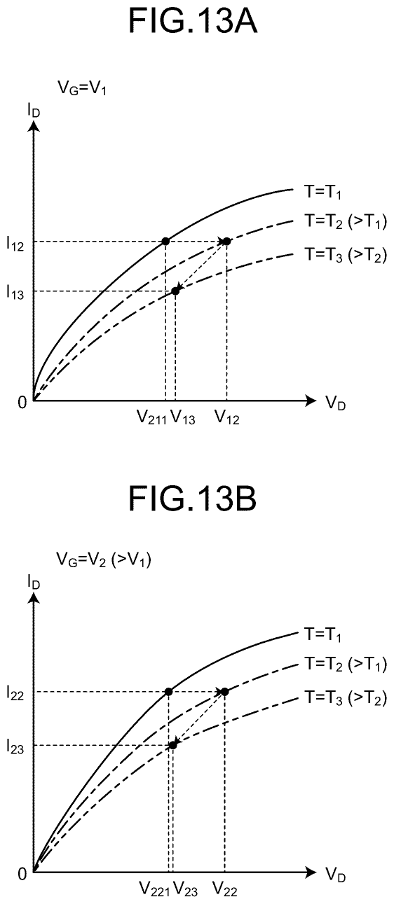

An operation of the temperature compensation circuit 4 may be an operation that is a combination of the operation illustrated in FIGS. 7A and 7B and the operation illustrated in FIGS. 12A and 12B. The temperature compensation circuit 4 may operate as illustrated in FIGS. 13A and 13B. FIGS. 13A and 13B are diagrams illustrating an operation of the temperature compensation circuit 4 according to a fourth variation of the embodiment.

In the temperature compensation circuit 4, the correction circuit 41 generates a correction signal that corresponds to the temperature T of the power device PT and the voltage V_{G} of the control terminal G. The correction circuit 41 may generate, for each of the voltages V_{G}, a correction signal that provides an instruction of correction to a threshold voltage Vth that causes a current of the power device PT to be maintained constant at different temperatures T, in a first temperature range, and may generate a correction signal that provides an instruction of correction to a threshold voltage Vth that corresponds to a rated current of the power device PT at temperature T, in a second temperature range.

For example, in a case where voltage V_{G}=V₁, a relationship between the voltage V_{D} across the power transistor PT and the current I_{D} is as illustrated in FIG. 13A. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that current I_{D} to be maintained at different temperatures T (T=T₁ and T₂)=I₁₂, and rated current I_{D} in a case where temperature T=T₂ and T₃=I₁₂ and I₁₃, respectively. In a case where temperature T=T₁ and T₂, respective voltages V_{D} (V_{D}=V₂₁₁ and V₁₂) in a case where current I_{D}=I₁₂ may be set as a correction target level of the threshold voltage. V₂₁₁ and V₁₂ increase in this order. In a case where temperature T=T₂ and T₃, respective voltages V_{D} (V_{D}=V₁₂ and V₁₃) in a case where current I_{D}=I₁₂ and I₁₃ may be set as a correction target level of the threshold voltage. V₁₂ and V₁₃ decrease in this order.

The correction circuit 41 generates a correction signal including an instruction to correct the level of the threshold voltage to level V₂₁₁ in a case where (T, V_{G})=(T₁, V₁), and supplies the correction signal to the voltage supply circuit 42. The voltage supply circuit 42 corrects the level of the threshold voltage Vth to level V₂₁₁ in response to the correction signal, and supplies the threshold voltage Vth to the input node 31b of the comparator circuit 31.

The correction circuit 41 generates a correction signal including an instruction to correct the level of the threshold voltage to level V₁₂ in a case where (T, V_{G})=(T₂, V₁), and supplies the correction signal to the voltage supply circuit 42. The voltage supply circuit 42 corrects the level of the threshold voltage Vth to level V₁₂ in response to the correction signal, and supplies the threshold voltage Vth to the input node 31b of the comparator circuit 31.

The correction circuit 41 generates a correction signal including an instruction to correct the level of the threshold voltage to level V₁₃ in a case where (T, V_{G})=(T₃, V₁), and supplies the correction signal to the voltage supply circuit 42. The voltage supply circuit 42 corrects the level of the threshold voltage Vth to level V₁₃ in response to the correction signal, and supplies the threshold voltage Vth to the input node 31b of the comparator circuit 31.

As another example, in a case where voltage V_{G}=V₂ (>V₁), a relationship between the voltage V_{D} across the power transistor PT and the current I_{D} is as illustrated in FIG. 13B. If temperature T=T₁, the relationship changes as illustrated with a solid line, if the temperature T is higher, that is, T=T₂ (>T₁), the relationship changes on a lower current side, as illustrated with a dash-dotted line, and if the temperature T is even higher, that is, T=T₃ (>T₂), the relationship changes on an even lower current side, as illustrated with a dash-double-dotted line.

It is assumed that current I_{D} to be maintained at different temperatures T (T=T₁ and T₂)=I₂₂, and rated current I_{D} in a case where temperature T=T₂ and T₃=I₂₂ and I₂₃, respectively. In a case where temperature T=T₁ and T₂, respective voltages V_{D} (V_{D}=V₂₂₁ and V₂₂) in a case where current I_{D}=I₂₂ may be set as a correction target level of the threshold voltage. V₂₂₁ and V₂₂ increase in this order. In a case where temperature T=T₂ and T₃, respective voltages V_{D} (V_{D}=V₂₂ and V₂₃) in a case where current I_{D}=I₂₂ and I₂₃ may be set as a correction target level of the threshold voltage. V₂₂ and V₂₃ decrease in this order.

The correction circuit 41 generates a correction signal including an instruction to correct the level of the threshold voltage to level V₂₂₁ in a case where (T, V_{G})=(T₁, V₂), and supplies the correction signal to the voltage supply circuit 42. The voltage supply circuit 42 corrects the level of the threshold voltage Vth to level V₂₂₁ in response to the correction signal, and supplies the threshold voltage Vth to the input node 31b of the comparator circuit 31.

The correction circuit 41 generates a correction signal including an instruction to correct the level of the threshold voltage to level V₂₂ in a case where (T, V_{G})=(T₂, V₂), and supplies the correction signal to the voltage supply circuit 42. The voltage supply circuit 42 corrects the level of the threshold voltage Vth to level V₂₂ in response to the correction signal, and supplies the threshold voltage Vth to the input node 31b of the comparator circuit 31.

The correction circuit 41 generates a correction signal including an instruction to correct the level of the threshold voltage to level V₂₃ in a case where (T, V_{G})−(T₃, V₂), and supplies the correction signal to the voltage supply circuit 42. The voltage supply circuit 42 corrects the level of the threshold voltage Vth to level V₂₃ in response to the correction signal, and supplies the threshold voltage Vth to the input node 31b of the comparator circuit 31.

Note that in a case where the temperature compensation circuit 4 is configured as illustrated in FIG. 4, the control circuit 8 may set a gain that corresponds to an increase T₁->T₂->T₃ in a signal of the temperature T for the variable amplifier AM1, and may set a gain that corresponds to an increase V₁->V₂ of a signal of the voltage V_{G} for the variable amplifier AM2.

An operation of the temperature compensation circuit 4, as above, enables the current I_{D} of the power transistor PT to be maintained constant at different temperatures T, in the first temperature range, and therefore malfunction of the load LD can be easily analyzed when overcurrent has flowed from the load LD. Furthermore, in the second temperature range, DESAT detection of the power device PT can be performed by using a threshold voltage Vth that corresponds to the temperature T and the voltage V_{G} of the control terminal G while a current margin of the power device PT is secured.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A temperature compensation circuit comprising:
a correction circuit that includes a first input node, a second input node, and an output node, the first input node being connected to a temperature sensor near a power device, the second input node being connected to a control terminal of the power device; and
a voltage supply circuit that includes an input node and an output node, the input node being connected to the output node of the correction circuit, the output node being connected to a second input node of a comparator circuit that includes the first input node and the second input node, the first input node being connected to one end of the power device.

2. The temperature compensation circuit according to claim 1, wherein
the correction circuit generates a correction signal that corresponds to a temperature of the power device, and a voltage of the control terminal, and
the voltage supply circuit corrects a threshold voltage in response to the correction signal, and supplies the threshold voltage that has been corrected to the second input node of the comparator circuit.

3. The temperature compensation circuit according to claim 1, wherein
the voltage supply circuit does not correct a threshold voltage during a first period when the comparator circuit outputs a first comparison result, and corrects the threshold voltage during a second period when the comparator circuit outputs a second comparison result.

4. The temperature compensation circuit according to claim 1, wherein
the correction circuit includes:
a first amplifier that has a variable gain, and includes an input node that is connected to the temperature sensor near the power device, and an output node;
a second amplifier that has the variable gain, and includes an input node that is connected to the control terminal of the power device, and an output node; and
a signal generation circuit that includes a first input node that is connected to the output node of the first amplifier, a second input node that is connected to the output node of the second amplifier, and an output node.

5. The temperature compensation circuit according to claim 1, wherein
the correction circuit includes:
a first AD conversion circuit that includes an input node that is connected to the temperature sensor near the power device, and an output node;
a second AD conversion circuit that includes an input node that is connected to the control terminal of the power device, and an output node;
an information conversion circuit that includes a first input node that is connected to the output node of the first AD conversion circuit, a second input node that is connected to the output node of the second AD conversion circuit, and an output node, the information conversion circuit holding correction information in which temperature, a voltage of the control terminal, and a threshold voltage have been associated with each other for a plurality of combinations of the temperature and the voltage of the control terminal; and
a DA conversion circuit that includes an input node that is connected to the output node of the information conversion circuit, and an output node.

6. The temperature compensation circuit according to claim 1, wherein
the correction circuit generates a first correction signal in a case where a temperature of the power device is a first temperature, and a voltage of the control terminal is a first voltage, and generates a second correction signal in a case where the temperature of the power device is a second temperature that is higher than the first temperature, and the voltage of the control terminal is the first voltage, and
the voltage supply circuit corrects a level of a threshold voltage to a first level in response to the first correction signal, and corrects the level of the threshold voltage to a second level in response to the second correction signal, the second level being lower than the first level.

7. The temperature compensation circuit according to claim 6, wherein
the first level corresponds to a rated current of the power device at the first temperature, and
the second level corresponds to the rated current of the power device at the second temperature.

8. The temperature compensation circuit according to claim 1, wherein
the correction circuit generates a first correction signal in a case where a temperature of the power device is a first temperature, and a voltage of the control terminal is a first voltage, and generates a third correction signal in a case where the temperature of the power device is a second temperature that is higher than the first temperature, and the voltage of the control terminal is the first voltage, and
the voltage supply circuit corrects a level of a threshold voltage to a first level in response to the first correction signal, and corrects the level of the threshold voltage to a third level in response to the third correction signal, the third level being higher than the first level.

9. The temperature compensation circuit according to claim 8, wherein
the first level corresponds to a first current of the power device, and
the third level corresponds to the first current of the power device.

10. A semiconductor integrated circuit comprising:
a protection circuit that includes a comparator circuit and a signal generation circuit, the comparator circuit including a first input node that is connected to one end of a power device, a second input node, and an output node, the signal generation circuit including an input node that is connected to the output node of the comparator circuit, and an output node;
the temperature compensation circuit according to claim 1, the temperature compensation circuit including a first input node, a second input node, and an output node, the first input node being connected to a temperature sensor near the power device, the second input node being connected to a control terminal of the power device, the output node being connected to the second input node of the comparator circuit; and
a driving circuit that includes an input node that is connected to the output node of the signal generation circuit, and an output node that is connected to the control terminal of the power device.

11. A semiconductor device comprising:
the semiconductor integrated circuit according to claim 10; and
a rectifying element that is connected between the semiconductor integrated circuit and one end of the power device.

12. A temperature compensation method comprising:
determining a threshold voltage that corresponds to a temperature of a power device and a voltage of a control terminal; and
supplying the threshold voltage that has been determined to a second input node of a comparator circuit that includes a first input node and the second input node, the first input node being connected to one end of the power device.

13. The temperature compensation method according to claim 12, wherein
the determining includes
determining that the threshold voltage has a first level, in a case where the temperature of the power device is a first temperature, and the voltage of the control terminal is a first voltage, and determining that the threshold voltage has a second level that is lower than the first level, in a case where the temperature of the power device is a second temperature that is higher than the first temperature, and the voltage of the control terminal is the first voltage.

14. The temperature compensation method according to claim 13, wherein
the first level corresponds to a rated current of the power device at the first temperature, and
the second level corresponds to the rated current of the power device at the second temperature.

15. The temperature compensation method according to claim 12, wherein
the determining includes
determining that the threshold voltage has a first level, in a case where the temperature of the power device is a first temperature, and the voltage of the control terminal is a first voltage, and determining that the threshold voltage has a third level that is higher than the first level, in a case where the temperature of the power device is a second temperature that is higher than the first temperature, and the voltage of the control terminal is the first voltage.

16. The temperature compensation method according to claim 15, wherein
the first level corresponds to a first current of the power device, and
the third level corresponds to the first current of the power device.
